(19) United States
(12) Patent Application Publication
(10) Pub. No.: US 2008/0245414 A1
(43) Pub. Date: Oct. 9, 2008

(54) METHODS FOR FORMING A PHOTOVOLTAIC DEVICE WITH LOW CONTACT RESISTANCE

(76) Inventors: Shuran Sheng, Sunnyvale, CA (US); Yong Kee Chae, Pleasanton, CA (US); Tae Kyung Won, San Jose, CA (US); Liwei Li, Sunnyvale, CA (US); Soo Young Choi, Fremont, CA (US); Yanping Li, Mountain View, CA (US); Joe Griffith Cruz, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/733,184

(22) Filed: Apr. 9, 2007

(51) Int. Cl. H01L 31/00

(52) U.S. Cl. 136/261; 427/74

(57) ABSTRACT

An improved PV solar cell structure and methods for manufacturing the same are provided. In one embodiment, a photovoltaic device includes a first photoelectric conversion unit, a first transparent conductive oxide layer and a first microcrystalline silicon layer disposed between and in contact with the photoelectric conversion unit and the transparent conductive oxide layer. In another embodiment, a method of forming a photovoltaic solar cell includes providing a substrate having a first transparent conductive oxide layer disposed thereon, depositing a first microcrystalline silicon layer on the transparent conductive oxide layer, and forming a first photoelectric conversion unit on the microcrystalline silicon layer.

### CROSS-REFERENCE TO RELATED APPLICATIONS

This application is related to U.S. patent application Ser. No. 11/624,677, entitled “MULTI-JUNCTION SOLAR CELLS AND METHODS AND APPARATUS FOR FORMING THE SAME,” filed on Jan. 18, 2007, which is herein incorporated by reference in its entirety.

### BACKGROUND OF THE DISCLOSURE

1. Field of the Invention

The present invention relates to methods for forming a microcrystalline silicon film for photovoltaic devices.

2. Description of the Background Art

Photovoltaic devices (PV) or solar cells are devices which convert sunlight into direct current (DC) electrical power. PV or solar cells typically have one or more p-i-n junctions. Each junction comprises two different regions within an i-type semiconductor material where one side is denoted as the p-type region and the other as the n-type region. When the p-i-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with specific frames and connectors.

Typically, a PV solar cell includes a photoelectric conversion unit and a transparent conductive oxide (TCO) film disposed as a front electrode on the bottom of the PV solar cell in contact with a glass substrate and/or as a back surface electrode on the top of the PV solar cell. The photoelectric conversion unit includes a p-type silicon layer, a n-type silicon layer and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si) and the like may be utilized to form the p-type, n-type and i-type layers of the photoelectric conversion unit. As the transparent conductive oxide (TCO) film is disposed on and in contact with p-type and/or n-type silicon films of the photoelectric conversion unit, the electrical properties of the interfacial contact may significantly influence the overall electrical performance of the PV solar cell. Poor electrical properties of the interfacial contact may result in low photoelectric conversion efficiency and high contact barrier, thereby causing device failure and high power consumption of the PV solar cells.

Therefore, there is a need for an improved structure and methods for forming a PV solar cell with good interfacial contact, low contact resistance and high overall electrical device performance of the PV solar cells.

### SUMMARY OF THE INVENTION

The present invention provides a structure of a PV solar cell with low contact resistance and high photoelectric conversion efficiency and methods for manufacturing the same. In one embodiment, a photovoltaic device includes a first photoelectric conversion unit, a first transparent conductive oxide layer and a first microcrystalline silicon layer disposed between and in contact with the photoelectric conversion unit and the transparent conductive oxide layer.

In another embodiment, a photovoltaic device includes a first microcrystalline silicon layer disposed between and in contact with a first photoelectric conversion unit and a first transparent conductive oxide layer disposed on a substrate, a second microcrystalline silicon layer disposed on the top of the first photoelectric conversion unit, and a second transparent conductive oxide layer disposed on the second microcrystalline silicon layer.

In yet another embodiment, a method of forming a photovoltaic solar cell includes providing a substrate having a first transparent conductive oxide layer disposed thereon, depositing a first microcrystalline silicon layer on the transparent conductive oxide layer, and forming a first photoelectric conversion unit on the microcrystalline silicon layer.

In still another embodiment, a method of forming a photovoltaic solar cell includes providing a substrate having a first transparent conductive oxide layer disposed thereon, depositing a p-type microcrystalline silicon layer on the transparent conductive oxide layer in a first processing chamber, depositing a p-type amorphous silicon layer on the p-type microcrystalline silicon layer in the first processing chamber, depositing an i-type amorphous silicon layer on the p-type amorphous silicon layer, depositing a n-type amorphous silicon layer on the i-type amorphous silicon layer in a second processing chamber, and depositing a n-type microcrystalline silicon layer on the n-type amorphous silicon layer in the second processing chamber.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of one embodiment of a process chamber in accordance with the invention;

FIG. 2 depicts an exemplary cross sectional view of a silicon-based thin film PV solar cell in accordance with one embodiment of the present invention;

FIG. 3 depicts a process flow diagram for forming a PV solar cell in accordance with the embodiment of FIG. 2;

FIG. 4 depicts an exemplary cross sectional view of a tandem type solar cell 400 in accordance with one embodiment of the present invention;

FIG. 5 depicts an exemplary cross sectional view of a triple junction PV solar cell 500 in accordance with one embodiment of the present invention; and

FIG. 6 is a top schematic view of one embodiment of a process system having a plurality of process chambers.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a structure of a PV solar cell with low contact resistance and high photoelectric conversion efficiency and methods for manufacturing the same. In one embodiment, a microcrystalline silicon (μc-Si) layer is disposed between an amorphous silicon (a-Si) based photoelectric conversion unit and a TCO layer to enhance the electrical properties of interfacial contact between the photoelectric conversion unit and the TCO layer.

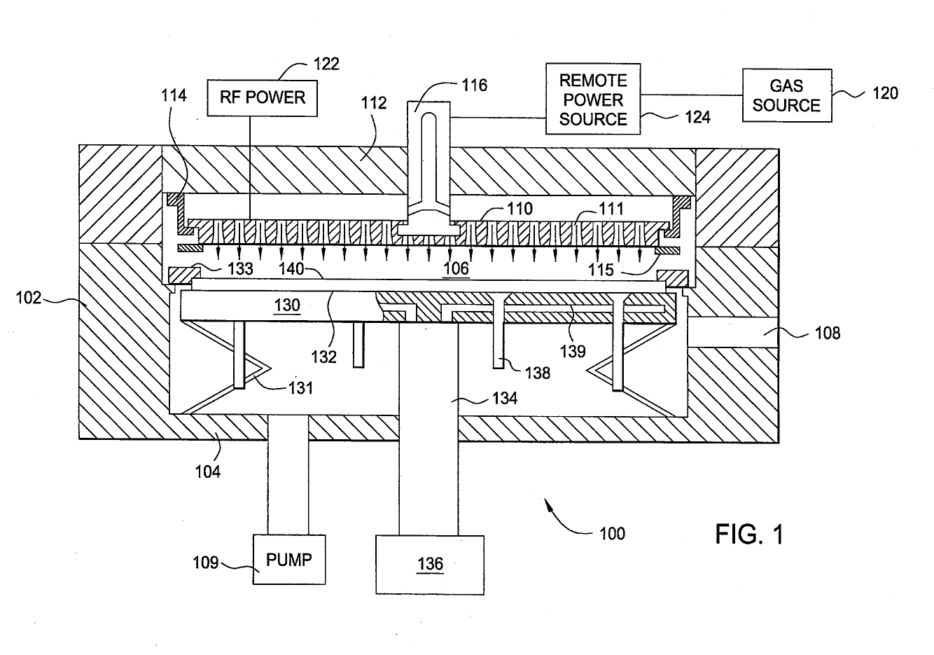

FIG. 1 is a schematic cross-section view of one embodiment of a plasma enhanced chemical vapor deposition (PECVD) chamber 100 in which one or more films of a solar cell. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 100 generally includes walls 102, a bottom 104, a showerhead 110, and substrate support 130 which define a process volume 106. The process volume is accessed through a valve 108 such that the substrate, such as substrate 140, may be transferred in and out of the chamber 100. The substrate support 130 includes a substrate receiving surface 132 for supporting a substrate and a stem 134 coupled to a lift system 136 to raise and lower the substrate support 130. A shadow frame 133 may be optionally placed over periphery of the substrate 140. Lift pins 138 are moveably disposed through the substrate support 130 to move a substrate to and from the substrate receiving surface 132. The substrate support 130 may also include heating and/or cooling elements 139 to maintain the substrate support 130 at a desired temperature. The substrate support 130 may also include grounding straps 131 to provide RF grounding at the periphery of the substrate support 130. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure.

The showerhead 110 is coupled to a backing plate 112 at its periphery by a suspension 114. The showerhead 110 may also be coupled to the backing plate by one or more center supports 116 to help prevent sag and/or control the straightness/curvature of the showerhead 110. A gas source 120 is coupled to the backing plate 112 to provide gas through the backing plate 112 and through the showerhead 110 to the substrate receiving surface 132. A vacuum pump 109 is coupled to the chamber 100 to control the process volume 106 at a desired pressure. An RF power source 122 is coupled to the backing plate 112 and/or to the showerhead 110 to provide a RF power to the showerhead 110 so that an electric field is created between the showerhead 110 and the substrate support 130 so that a plasma may be generated from the gases between the showerhead 110 and the substrate support 130. Various RF frequencies may be used, such as a frequency between about 0.3 MHz and about 200 MHz. In one embodiment the RF power source is provided at a frequency of 13.56 MHz. Examples of showerheads are disclosed in U.S. Pat. No. 6,477,980 issued on Nov. 12, 2002 to White et al., U.S. Publication 20050251990 published on Nov. 17, 2006 to Choi et al., and U.S. Publication 2006/0060138 published on Mar. 23, 2006 to Keller et al, which are all incorporated by reference in their entirety to the extent not inconsistent with the present disclosure.

A remote plasma source 124, such as an inductively coupled remote plasma source, may also be coupled between the gas source and the backing plate. Between processing substrates, a cleaning gas may be provided to the remote plasma source 124 so that a remote plasma is generated and provided to clean chamber components. The cleaning gas may be further excited by the RF power source 122 provided to the showerhead. Suitable cleaning gases include, but are not limited to, NF₃, F₂, and SF₆. Examples of remote plasma sources are disclosed in U.S. Pat. No. 5,788,778 issued Aug. 4, 1998 to Shang et al, which is incorporated by reference to the extent not inconsistent with the present disclosure.

In one embodiment, the substrate 140 that may be deposited in the chamber 100 may have a surface area of 10,000 cm² or more, such as 40,000 cm² or more, for example about 55,000 cm² or more. It is understood that after processing the substrate may be cut to form smaller solar cells.

In one embodiment, the heating and/or cooling elements 139 may be set to provide a substrate support temperature during deposition of about 400 degrees Celsius or less, preferably between about 100 degrees Celsius and about 400 degrees Celsius, more preferably between about 150 degrees Celsius and about 300 degrees Celsius, such as about 200 degrees Celsius.

The spacing during deposition between the top surface of a substrate disposed on the substrate receiving surface 132 and the showerhead 110 may be between 400 mil and about 1,200 mil, preferably between 400 mil and about 800 mil.

For deposition of silicon films, a silicon-based gas and a hydrogen-based gas are provided. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). The p-type dopants of the p-type silicon layers may each comprise a group III element, such as boron or aluminum. In one embodiment, boron is used as the p-type dopant. Examples of boron-containing sources include trimethylborate (TMB), diborane (B₂H₆), BF₃, B(C₂H₅)₃, BH₃, BF₃, and B(CH₃)₃ and similar compounds. In one embodiment, TMB is used as the p-type dopant. The n-type dopants of the n-type silicon layer may each comprise a group V element, such as phosphorus, arsenic, or antimony. Examples of phosphorus-containing sources include phosphine and similar compounds. The dopants are typically provided with a carrier gas, such as hydrogen, argon, helium, and other suitable compounds. In the process regimes disclosed herein, a total flow rate of hydrogen gas is provided. Therefore, if a hydrogen gas is provided as the carrier gas, such as for the dopant, the carrier gas flow rate should be subtracted from the total flow rate of hydrogen to determine how much additional hydrogen gas should be provided to the chamber.

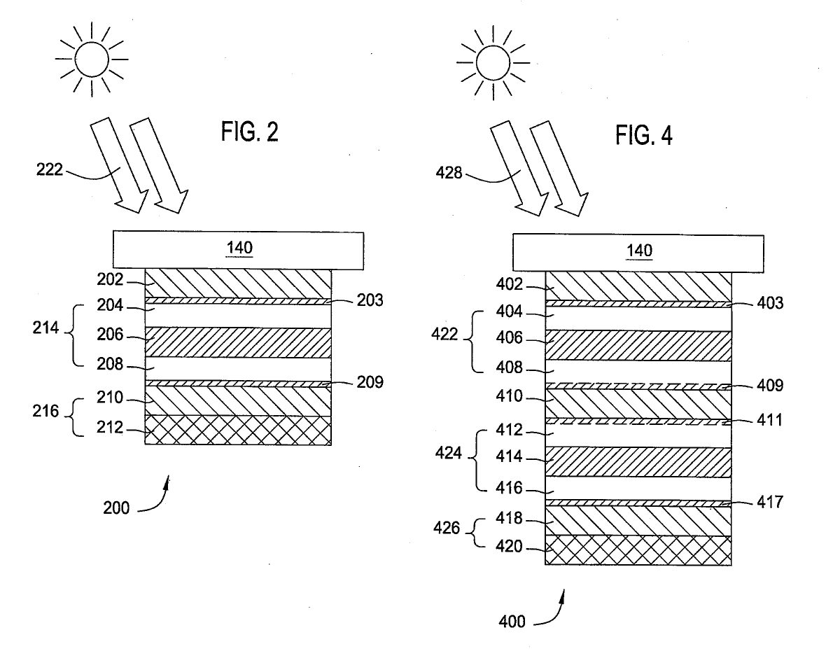

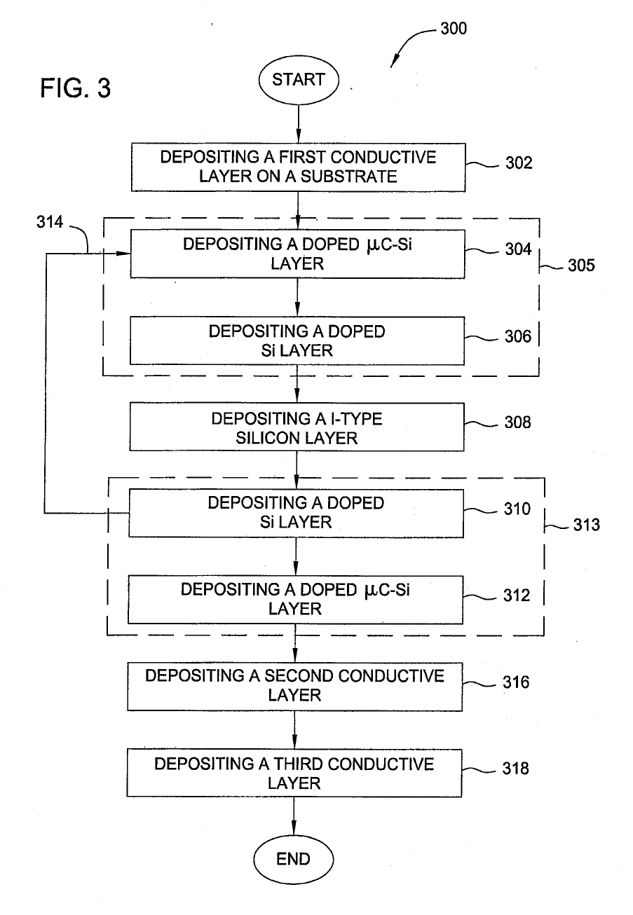

FIG. 2 depicts an exemplary cross sectional view of an amorphous silicon-based thin film PV solar cell 200 in accordance with one embodiment of the present invention. FIG. 3 depicts a flow diagram of a process for manufacturing a PV solar cell, such as the solar cell 200 of FIG. 2. The process may be performed in the system 100 of FIG. 1, or other suitable system.

The process 300 begins at step 302 by depositing a TCO layer 202 on a substrate 140, as shown in FIG. 2. The substrate 140 may be thin sheet of metal, plastic, organic material, silicon, glass, quartz, or polymer, among others suitable materials. The substrate 140 may have a surface area greater than about 1 square meters, such as greater than about 2 square meters. An optional dielectric layer (not shown) may be disposed between the substrate 140 and a transmitting conducting oxide (TCO) layer 202. In one embodiment, the optional dielectric layer may be a SiON or silicon oxide (SiO₂) layer. The transmitting conducting oxide (TCO) layer 202 may include, but not limited to, at least one oxide layer selected from a group consisting of tin oxide (SnO₂), indium tin oxide (ITO), zinc oxide (ZnO), or the combination thereof. The TCO layer 202 may be deposited by a CVD process, a PVD process, or other suitable deposition process.

In one embodiment, the TCO layer 202 may be deposited by a reactive sputter depositing process having predetermined film properties. The substrate temperature is controlled between about 150 degrees Celsius and about 350 degrees Celsius. Detail process and film property requirements are disclosed in detail by U.S. patent application Ser. No. 11/614,461, filed Dec. 21, 2006 by Li et al, title “Reactive Sputter Deposition of a Transparent Conductive Film” ”, and is herein incorporated by reference.

At step 304, a microcrystalline silicon layer 203 may be deposited on the TCO layer 202 before a photoelectric conversion unit 214 is formed as shown in FIG. 2. The photoelectric conversion unit 214 typically includes a p-type semiconductor layer 204, a n-type semiconductor layer 208, and an intrinsic type (i-type) semiconductor layer 206 as a photoelectric conversion layer, which will be further discussed in detail below. The microcrystalline silicon layer 203 disposed on the TCO layer 202 is in contact with the p-type semiconductor layer 204 of the photoelectric conversion unit 214. In one embodiment, the microcrystalline silicon layer 203 has a thickness between about 100 Å and about 500 Å.

In one embodiment, the microcrystalline silicon layer 203 may be doped by an element selected either from group III or V corresponding to the types of the surface and/or layer in the photoelectric conversion unit 214 which is in direct contact with the microcrystalline silicon layer 203. For example, in embodiments where the microcrystalline silicon layer 203 is in direct contact with a n-type semiconductor layer in a photoelectric conversion unit, the microcrystalline silicon layer 203 may be doped by a group V element, thereby forming the microcrystalline silicon layer 203 as a n-type microcrystalline silicon layer similar as the contacting n-type semiconductor layer. In embodiments where the microcrystalline silicon layer 203 is in direct contact with a p-type semiconductor layer in a photoelectric conversion unit, the microcrystalline silicon layer 203 may be doped by a group III element, thereby forming the microcrystalline silicon layer 203 as a p-type microcrystalline silicon layer similar as the contacting p-type semiconductor layer. In the embodiment depicted in FIG. 2, the microcrystalline silicon layer 203 is in direct contact with the p-type semiconductor layer 204 of the photoelectric conversion unit 214 and is doped by a group III element, thereby forming a p-type microcrystalline silicon layer.

In one embodiment, the p-type microcrystalline silicon layer 203 may be deposited in a CVD chamber, as the processing chamber 100 of FIG. 1. The substrate temperature during the deposition process is maintained at a predetermined range. In one embodiment, the substrate temperature is maintained at less than about 450 degrees Celsius so as to allow the substrates with low melt point, such as alkaline glasses, plastic and metal, to be utilized in the present invention. In another embodiment, the substrate temperature in the process chamber is maintained at a range between about 100 degrees Celsius to about 450 degrees Celsius. In yet another embodiment, the substrate temperature is maintained at a range about 150 degrees Celsius to about 400 degrees Celsius, such as 350 degrees Celsius.

During processing, a gas mixture is flowed into the process chamber 102 and used to form a RF plasma and deposit the p-type microcrystalline silicon layer 203. In one embodiment, the gas mixture includes a silane-based gas, a group III doping gas and a hydrogen gas (H₂). Suitable examples of the silane-based gas include, but not limited to, mono-silane (SiH₄), di-silane(Si₂H₆), silicon tetrafluoride (SiF₄), silicon tetrachloride(SiCl₄), and dichlorsilane (SiH₂Cl₂), and the like. The group III doping gas may be a boron containing gas selected from a group consisting of trimethylborate (TMB), diborane (B₂H₆), BF₃, B(C₂H₅)₃, BH₃, BF₃, and B(CH₃)₃. The supplied gas ratio among the silane-based gas, group III doping gas, and H₂ gas is maintained to control reaction behavior of the gas mixture, thereby allowing a desired proportion of the crystallization and dopant concentration to be formed in the p-type microcrystalline silicon layer 203. In one embodiment, the silane-based gas is SiH₄ and the group III doping gas is B(CH₃)₃. SiH₄ gas may be 1 sccm/L and about 20 sccm/L. H₂ gas may be provided at a flow rate between about 5 sccm/L and 500 sccm/L. B(CH₃)₃ may be provided at a flow rate between about 0.001 sccm/L and about 0.05 sccm/L. The process pressure is maintained at between about 1 Torr to about 20 Torr, for example, such as greater than about 3 Torr. An RF power between about 15 milliWatts/cm² and about 200 milliWatts/cm² may be provided to the showerhead.

Alternatively, one or more inert gases may be included with the gas mixture provided to the process chamber 102. The inert gas may include, but not limited to, noble gas, such as Ar, He, Xe, and the like. The inert gas may be supplied to the processing chamber 102 at a flow ratio between about 0 sccm/L and about 200 sccm/L.

In one embodiment, the processing spacing for a substrate having an upper surface area greater than 1 square meters is controlled between about 400 mils and about 1200 mils, for example, between about 400 mils and about 800 mils, such as 500 mils.

At step 306, a semiconductor layer 204 is deposited on the p-type microcrystalline silicon layer 203. The semiconductor layer 204 may be a silicon based materials doped by an element selected from either group III or group V. A group III element doped silicon film is referred to as a p-type silicon film, while a group V element doped silicon film is referred to as a n-type silicon film. The semiconductor layer 204 may be fabricated by an amorphous silicon film (a-Si), a polycrystalline film (poly-Si), and a microcrystalline film (μc-Si) with a thickness between around 5 nm and about 50 nm. In embodiment depicts in FIG. 2, the semiconductor layer 204 is fabricated by a boron doped amorphous silicon.

In one embodiment, the p-type amorphous silicon layer 204 may be deposited at the same processing chamber where the deposition of the microcrystalline silicon layer 203 is performed, as shown in phantom as process step 305 in FIG. 3. The deposition process of the microcrystalline silicon layer 203 and the p-type amorphous silicon layer 204 may be a consecutive deposition process without breaking the processing chamber vacuum. The substrate temperature for depositing the p-type amorphous silicon layer 204 at step 306 may be controlled as the substrate temperature processed at step 304 for depositing the microcrystalline silicon layer 203. The gas mixture supplied to the processing chamber may be varied to deposit the p-type amorphous silicon layer 204 having a desired film property different from the microcrystalline silicon layer 203. As the microcrystalline and amorphous silicon may have different crystalline volume, the gas mixture and process parameters may be changed during processing to deposit the films with different desired crystalline volume.

In one embodiment, the gas mixture supplied into the chamber at step 306 includes a silane-based gas, a group III doping gas and a carrier gas, such as hydrogen gas (H₂). Suitable examples of the silane-based gas include, but not limited to, mono-silane (SiH₄), di-silane (Si₂H₅), silicon tetrafluoride (SiF₄), silicon tetrachloride (SiCl₄), and dichlorsilane (SiH₂Cl₂), and the like. The group III doping gas may be a boron containing gas selected from a group consisting of trimethylborate (TMB), diborane (B₂H₆), BF₃, B(C₂H₅)₃, BH₃, BF₃, and B(CH₃)₃. The supplied gas ratio among the silane-based gas, group III doping gas, and H₂ gas is maintained to control reaction behavior of the gas mixture, thereby allowing a desired dopant concentration to be formed in the p-type amorphous silicon layer 204. In one embodiment, the silane-based gas is SiH₄ and the group III doping gas is BH₃. SiH₄ gas may be 1 sccm/L and about 10 sccm/L. H₂ gas may be provided at a flow rate between about 5 sccm/L and 60 sccm/L. B(CH₃)₃ may be provided at a flow rate between about 0.005 sccm/L and about 0.05 sccm/L. In other words, if B(CH₃)₃ is provided in a 0.5% molar or volume concentration in a carrier gas, then the dopant/carrier gas mixture may be provided at a flow rate between about 1 sccm/L and about 10 sccm/L. Methane may be provided at a flow rate between about 1 sccm/L and 15 sccm/L. The process pressure is maintained at between about 1 Torr to about 20 Torr, for example, such as greater than about 3 Torr. An RF power between about 15 milliWatts/cm² and about 200 milliWatts/cm² may be provided to the showerhead.

At the steps 304, 306 for depositing the microcrystalline silicon layer 203 and the semiconductor layer 204, the process gas flow may be varied to achieve different crystalline volume in different films. In embodiments where a higher crystalline volume is desired, a high amount of H₂ flow may be supplied into the processing chamber. The substrate may be controlled at a substantially similar process temperature.

At step 308, an i-type semiconductor layer 206 is deposited on the p-type amorphous silicon layer 204. The i-type semiconductor layer 206 is a non-doped silicon based film. The i-type semiconductor layer 206 may be deposited under process condition controlled to provide film properties having improved photoelectric conversion efficiency. In one embodiment, the i-type semiconductor layer 206 includes i-type polyscrystalline silicon (poly-Si), i-type microcrystalline silicon film (μc-Si), or i-type amorphous silicon film (a-Si). In embodiment depicted in FIG. 2, the i-type semiconductor layer 206 is an amorphous silicon film and may be deposited in the processing chamber 102 of FIG. 1 or other suitable processing chambers. The i-type amorphous silicon-based film 206 may be deposited in any suitable manner.

In one embodiment, substrate temperature for depositing the i-type amorphous silicon 206 is maintained at less than about 400 degrees Celsius, such as at a range about 150 degrees Celsius to about 400 degrees Celsius, such as 200 degrees Celsius. Detail process and film property requirements are disclosed in detail by U.S. patent application Ser. No. 11/426,127, filed Jun. 23, 2006 by Choi, et al., title “Method and Apparatus for Depositing a Microcrystalline Silicon Film For Photovoltaic Device”, and is herein incorporated by reference.

In one embodiment, the i-type amorphous silicon 206 may be deposited in a chamber, such as the chamber 100 in FIG. 1 by supplying a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between 15 milliWatts/cm² and about 250 milliWatts/cm² may be provided to the showerhead. The pressure of the chamber may be maintained between about 0.1 Torr and 20 Torr, such as between about 0.5 Torr and about 5 Torr. The deposition rate of the intrinsic type amorphous silicon layer may be about 100 Å/min or more.

At step 310, a semiconductor layer 208 is deposited on the i-type amorphous silicon-based film 206. The semiconductor layer 208 may be a silicon based materials doped by an element selected from either group III or group V other than the group selected for doping in the semiconductor layer 204. For example, as a group III element is selected to be doped into the semiconductor layer 204 as a p-type layer, a group V element is selected to be doped into the semiconductor layer 208 as a n-type layer. As the photoelectric conversion unit 214 of FIG. 2 formed the semiconductor layer 204 as a p-type layer, the semiconductor layer 208 may be formed as a n-type semiconductor layer having phosphorus elements doped therein. In one embodiment, the n-type semiconductor layer 208 may be fabricated by an amorphous silicon film (a-Si), a polycrystalline film (poly-Si), and a microcrystalline film (PC-Si) with a thickness between around 5 nm and about 50 nm. In embodiment depicts in FIG. 2, the n-type semiconductor layer 208 is fabricated by a phosphorous doped amorphous silicon.

In one embodiment, the substrate temperature controlled for depositing the n-type amorphous layer 208 is controlled at a temperature lower than the temperature for depositing the p-type amorphous layer 204 and i-type amorphous layer 206. As the i-type amorphous layer 206 has been deposited on the substrate 140 with a desired crystalline volume and film property, a relatively lower process temperature is performed to deposit the n-type amorphous layer 208 to prevent the underlying amorphous silicon layers 204, 206 from thermal damage and grain reconstruction. In one embodiment, the substrate temperature at step 310 is controlled at a temperature lower than about 350 degree Celsius. In another embodiment, the substrate temperature is controlled at a temperature between about 100 degree Celsius and about 300 degree Celsius, such as between about 150 degree Celsius and about 250 degree Celsius, for example, about 200 degree Celsius.

During processing, a gas mixture is flowed into the process chamber 102 and used to form a RF plasma and deposit the n-type amorphous silicon layer 208. In one embodiment, the gas mixture includes a silane-based gas, a group V doping gas and a hydrogen gas (H₂). Suitable examples of the silane-based gas include, but not limited to, mono-silane (SiH₄), di-silane (Si₂H₆), silicon tetrafluoride (SiF₄), silicon tetrachloride (SiCl₄), and dichlorsilane (SiH₂Cl₂), and the like. The group V doping gas may be a boron containing gas selected from a group consisting of PH₃, P₂H₅, PO₃, PF₃, PF₅, and PCl₃. The supplied gas ratio among the silane-based gas, Group V doping gas, and H₂ gas is maintained to control reaction behavior of the gas mixture, thereby allowing a desired dopant concentration to be formed in the n-type amorphous layer 208. In one embodiment, the silane-based gas is SiH₄ and the Group V doping gas is PH₃. SiH₄ gas may be provided at a flow rate between about 1 sccm/L and about 10 sccm/L. H₂ gas may be provided at a flow rate between about 4 sccm/L and about 50 sccm/L. PH₃ may be provided at a flow rate between about 0.0005 sccm/L and about 0.0075 sccm/L. In other words, if phosphine is provided in a 0.5% molar or volume concentration in a carrier gas, such as H₂ gas, then the dopant/carrier gas mixture may be provided at a flow rate between about 0.1 sccm/L and about 1.5 sccm/L. An RF power between about 15 milliWatts/cm² and about 250 milliWatts/cm² may be provided to the showerhead. The pressure of the chamber may be maintained between about 0.1 Torr and 20 Torr, preferably between about 0.5 Torr and about 4 Torr. The deposition rate of the n-type amorphous silicon buffer layer may be about 200 Å/min or more.

Alternatively, one or more inert gases may be included with the gas mixture provided to the process chamber 102. The inert gas may include, but not limited to, noble gas, such as Ar, He, Xe, and the like. The inert gas may be supplied to the processing chamber 102 at a flow ratio between about 0 sccm/L and about 200 sccm/L.

In one embodiment, the processing spacing for a substrate having an upper surface area greater than 1 square meters is controlled between about 400 mils and about 1200 mils, for example, between about 400 mils and about 800 mils, such as 500 mils.

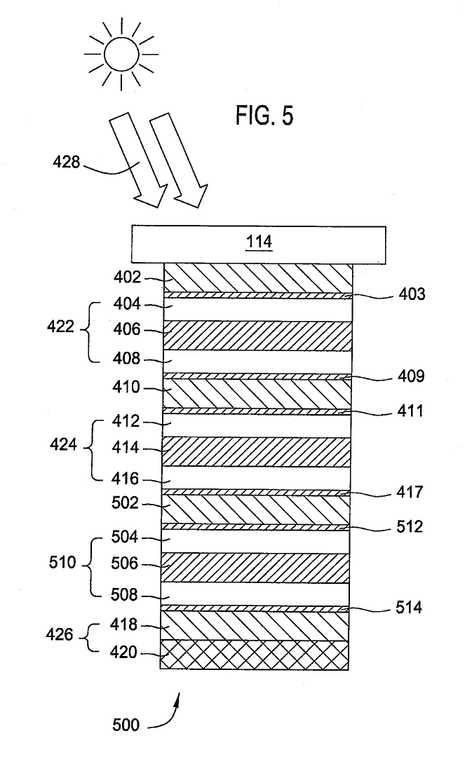

Although the embodiment of FIG. 2 depicts a single junction photoelectric conversion unit formed on the substrate 140, a different number of photoelectric conversion units, e.g., more than one, may be formed on the photoelectric conversion unit 214 to meet different process requirements and device performance as is further discussed below with reference to FIGS. 4 and 5. In embodiments where multiple junctions are desired, the steps from 306 to 310 may be repeatedly performed as indicated by loop 314 of FIG. 3 to form as many as photoelectric conversion units as desired.

At step 312, a microcrystalline silicon layer 209 is deposited on the n-type amorphous layer 208. The microcrystalline silicon layer 209 may be doped by either a group III or group V corresponding to the dopants present in the layer in contact with the microcrystalline silicon layer 209. In the embodiment depicted in FIG. 2, the microcrystalline silicon layer 209 is in direct contact with the n-type amorphous layer 208 and accordingly may be formed as a n-type microcrystalline silicon layer having a substantially similar dopants as the n-type amorphous layer 208. In another embodiment, the microcrystalline silicon layer 209 may be a n-type microcrystalline silicon layer doped by an element selected from group V, such as phosphorous. In yet another embodiment, the n-type microcrystalline silicon layer 209 has a thickness between about 100 Å and about 500 Å.

In one embodiment, the n-type microcrystalline silicon layer 209 may be deposited in a CVD chamber, as the processing chamber 100 as depicted in FIG. 1. The n-type microcrystalline silicon layer 209 may be deposited at the same processing chamber where the deposition of the n-type amorphous layer 208 is performed, as shown in phantom step 313 in FIG. 3. The deposition process of the n-type microcrystalline silicon layer 209 and the n-type amorphous layer 208 may be a consecutive deposition process without breaking the processing chamber vacuum. The substrate temperature for depositing the n-type microcrystalline silicon layer 209 at step 312 may be controlled as the substrate temperature processed at step 310 for depositing the n-type amorphous layer 208. The gas mixture supplied to the processing chamber may be varied to deposit the n-type microcrystalline silicon layer 209 having a desired crystalline volume and film properties different from the n-type amorphous layer 208. As the microcrystalline and amorphous silicon may have different crystalline volume, the gas mixture and process parameters may be changed during processing at steps 310 and 312 to deposit the films with different desired crystalline volume.

The substrate temperature at step 312 is maintained at a substantially similar temperature range as performed at step 310. In one embodiment, the process temperature is controlled at a temperature lower than about 350 degree Celsius. In another embodiment, the substrate temperature is controlled at a temperature between about 100 degree Celsius and about 300 degree Celsius, such as between about 150 degree Celsius and about 250 degree Celsius, for example, about 200 degree Celsius.

At the steps 310, 312 for depositing the microcrystalline silicon layer 208 and the semiconductor layer 209, the process gas flow may be varied to achieve different crystalline volume in different films. In embodiments where a higher crystalline volume is desired, a high amount of H₂ flow may be supplied into the processing chamber. The substrate may be controlled at a substantially similar process temperature.

Referring back to FIG. 2, after the n-type microcrystalline silicon layer 209 is formed on the photoelectric conversion unit 214, a second conductive layer, such as a backside electrode 216, is disposed on the photoelectric conversion unit 214 at step 316. In one embodiment, the backside electrode 216 may be formed by a stacked film that includes a transmitting conducting oxide (TCO) layer 210 and a conductive layer 212. The conductive layer 212 may include, but not limited to, a metal layer selected from a group consisting of Ti, Cr, Al, Ag, Au, Cu, Pt, or an alloy of the combination thereof. The transmitting conducting oxide (TCO) layer 210 may be fabricated from a material similar as the TCO layer 202 formed on the substrate. Suitable transmitting conducting oxide (TCO) layer 210 include, but not limited to, tin oxide (SnO₂), indium tin oxide (ITO), zinc oxide (ZnO), or the combination thereof. The metal layer 212 and TCO layer 210 may be deposited by a CVD process, a PVD process, or other suitable deposition process.

In one embodiment, the TCO layer 210 may be deposited by a reactive sputter depositing process and have similar film properties as the TCO layer 202. As the TCO layer 210 is deposited on the photoelectric conversion unit 214, a relatively low process temperature is utilized to prevent the silicon layers in the photoelectric conversion unit 214 from thermal damage and undesired grain reconstruction. In one embodiment, the substrate temperature is controlled between about 150 degrees Celsius and about 300 degrees Celsius, such as between about 200 degrees Celsius and about 250 degrees Celsius. One example of a suitable deposition process is disclosed in detail by U.S. patent application Ser. No. 11/614,461, filed Dec. 21, 2006 by Li et al, title “Reactive Sputter Deposition of a Transparent Conductive Film”, and is herein incorporated by reference. Alternatively, the PV solar cell 200 may be fabricated or deposited in a reversed order. For example, the substrate 140 may be disposed over backside electrode 216.

In operation, incident light 222 provided by the environment, e.g, sunlight or other photons, is provided to the PV solar cell 200. The photoelectric conversion unit 214 in the PV solar cell 200 absorbs the light energy and converts the light energy into electrical energy by the operation of the p-i-n junctions formed in the photoelectric conversion unit 214, thereby generating electricity or energy.

FIG. 4 depicts an exemplary cross sectional view of a tandem type PV solar cell 400 in accordance with another embodiment of the present invention. Tandem type PV solar cell 400 has a similar structure of the PV solar cell 200, including a TCO layer 402 formed on a sheet 140 and a first photoelectric conversion unit 422 formed on the TCO layer 402, as described above in FIG. 2. In one embodiment, the p-type, i-type, and n-type semiconductor layers 404, 406, 408 in the first photoelectric conversion unit 422 are deposited as an amorphous Si based film. A p-type microcrystalline silicon layer 403, similar to the p-type microcrystalline silicon layer 203 manufactured by the process 300 of FIG. 3, may be deposited between interface of the TCO layer 402 and p-type semiconductor layer 404 of the photoelectric conversion unit 422 to reduce contact resistance. Subsequently, another optional n-type microcrystalline silicon layer 409, similar to the n-type microcrystalline silicon layer 209, may be disposed between the n-type semiconductor layer 408 of the photoelectric conversion unit 422 and an optional interfacial layer 410. The optional interfacial layer 410 may be a TCO layer similar as the TCO layer 402 formed on the substrate 140. In embodiments where the interfacial TCO layer 410 is not present, the formation of the n-type microcrystalline silicon layer 409 may be eliminated as the n-type semiconductor layer 408 is not in direct contact with a conductive or a TCO layer. Alternatively, the p-type, i-type and n-type semiconductor layers 404, 406, 408 in the first photoelectric conversion unit 422 may be deposited as poly-Si based or microcrystalline silicon based film to meet different process requirements.

Subsequently, a second photoelectric conversion unit 424 is deposited on the interfacial TCO layer 410 or on the first photoelectric conversion unit 422 when the interfacial TCO layer 410 is not present. The combination of the first underlying conversion unit 422 and the second photoelectric conversion unit 424 increases the photoelectric conversion efficiency. In one embodiment, the second photoelectric conversion unit 424 may be an amorphous silicon based, having amorphous silicon films as the i-type amorphous silicon semiconductor layer 414 sandwiched between a p-type amorphous silicon semiconductor layer 412 and a n-type amorphous silicon semiconductor layer 416.

Similar to the structure of the first photoelectric conversion unit 422, a microcrystalline silicon layer 411 similar to the microcrystalline silicon layer 403 manufactured by process 300 may be formed on the interface of the interfacial TCO layer 410 and the p-type semiconductor amorphous silicon layer 412 of the second photoelectric conversion unit 424. The microcrystalline silicon layer 411 may be formed as a p-type semiconductor layer as it is in direct contact with the p-type semiconductor layer 412 in the photoelectric conversion unit 424. Another microcrystalline silicon layer 417 may be deposited between the photoelectric conversion unit 424 and a backside electrode 426. The backside electrode 426 may be similar to backside electrode 216 shown in FIG. 2. The backside electrode 426 may comprise a conductive layer 420 formed on a TCO layer 418. The materials of the conductive layer 420 and the TCO layer 418 may be similar to the conductive layer 212 and TCO layer 210 as shown in FIG. 2.

Alternatively, the second photoelectric conversion unit 424 may be a microcrystalline silicon based, having microcrystalline silicon films as the i-type microcrystalline silicon semiconductor layer 414 sandwiched between a p-type microcrystalline silicon semiconductor layer 412 and a n-type microcrystalline silicon semiconductor layer 416. In embodiments where the second photoelectric conversion unit 424 is a microcrystalline based silicon, the interfacial microcrystalline silicon layers 411, 417 may be eliminated as the silicon layers of the second photoelectric conversion unit 424, e.g. p-type and n-type semiconductor layer 412, 416, in contact with the TCO layers 410, 418 are microcrystalline silicon-based.

Thus, as a contact interface is created between a TCO layer and a silicon layer of a photoelectric conversion unit, a microcrystalline layer may be utilized to deposit between the silicon layer and the TCO layer to reduce contact resistance. The photoelectric conversion unit may be amorphous silicon based unit, microcrystalline silicon based unit, or combination thereof. In embodiment where the contact interface is created between a TCO layer and a microcrystalline based silicon layer of a photoelectric conversion unit, the microcrystalline layer that is disposed between the TCO layer and the microcrystalline based silicon layer of the photoelectric conversion unit may be optionally eliminated. Alternatively, the PV solar cell 400 may be fabricated or deposited in a reversed order. For example, the substrate 140 may be disposed over the backside electrode 426.

In operation, incident light 428 provided by the environment is supplied to the PV solar cell 400. The photoelectric conversion unit 422, 424 in the PV solar cell 400 absorbs the light energy and converts the light energy into electrical energy by operation of the p-i-n junctions formed in the photoelectric conversion unit 424, 422, thereby generating electricity or energy.

Alternatively, a third overlying photoelectric conversion unit 510 may be formed upon the second photoelectric conversion unit 424, as shown in FIG. 5. An optional interfacial layer 502 may be disposed between the second photoelectric conversion unit 424 and the third photoelectric conversion unit 510. The optional interfacial layer 502 may be a TCO layer similar to the TCO layers of 410, 402 as described in FIG. 4. The third photoelectric conversion unit 510 may be substantially similar to the second photoelectric conversion unit 424 having an i-type semiconductor layer 506 disposed between a p-type semiconductor layer 504 and a n-type layer 508. The third photoelectric conversion unit 510 may be an amorphous silicon type, a microcrystalline silicon type, or a polysilicon type photoelectric conversion unit. Interfacial microcrystalline silicon layers 512, 514 may be disposed between the TCO layers 502, 418 and the photoelectric conversion unit 510 as an interfacial microcrystalline silicon layer 403, 409, 411, 417, as depicted in FIG. 4. Alternatively, in embodiments where the third photoelectric conversion unit 510 is a microcrystalline silicon based unit, the interfacial microcrystalline layer 512, 514 may be optionally disposed for different process requirements. It should be noted that one or more photoelectric conversion units may optionally deposited on the third photoelectric conversion unit to promote photoelectric conversion efficiency.

In embodiment where a contact interface is created between a TCO layer and a silicon layer of a photoelectric conversion unit, the photoelectric conversion efficiency of the cell may be improve from about 7% to about 12%. The contact resistance, such as ohmic contact, may reduce from 25.3Ω per square to about 13.2Ω per square.

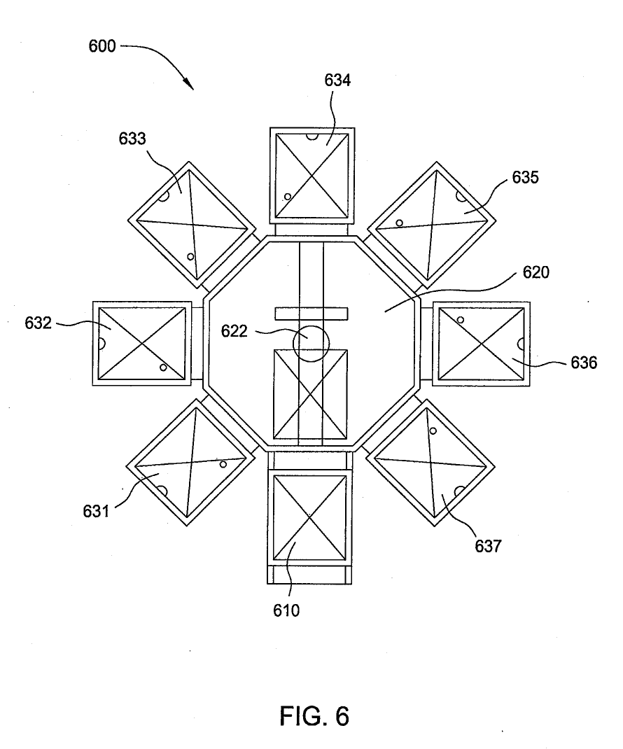

FIG. 6 is a top schematic view of one embodiment of a process system 600 having a plurality of process chambers 631-637, such as PECVD chambers chamber 100 of FIG. 1 or other suitable chambers capable of depositing silicon films. The process system 600 includes a transfer chamber 620 coupled to a load lock chamber 610 and the process chambers 631-637. The load lock chamber 610 allows substrates to be transferred between the ambient environment outside the system and vacuum environment within the transfer chamber 620 and process chambers 631-637. The load lock chamber 610 includes one or more evacuatable regions holding one or more substrate. The evacuatable regions are pumped down during input of substrates into the system 600 and are vented during output of the substrates from the system 600. The transfer chamber 620 has at least one vacuum robot 622 disposed therein that is adapted to transfer substrates between the load lock chamber 610 and the process chambers 631-637. Seven process chambers are shown in FIG. 6; however, the system may have any suitable number of process chambers.

Thus, an improved PV solar cell structure and methods for manufacturing the same are provided. The improved structure of the PV solar cell advantageously reduce contact resistance at the interface of a TCO layer and a photoelectric conversion unit, thereby increasing the photoelectric conversion efficiency and device performance of the PV solar cell as compared to conventional methods.

While the foregoing is directed to embodiments of the present invention, other and further embodiments of the invention may be devised without departing from the basic scope thereof, and the scope thereof is determined by the claims that follow.

What is claimed is:

1. A photovoltaic device, comprising:
a first photoelectric conversion unit;
a first transparent conductive oxide layer; and
a first microcrystalline silicon layer disposed between and in contact with the photoelectric conversion unit and the transparent conductive oxide layer.

2. The photovoltaic device of claim 1, wherein the first photoelectric conversion unit further comprises:
a p-type semiconductor layer;
a n-type semiconductor layer; and
an i-type semiconductor disposed between the p-type and n-type semiconductor layer.

3. The photovoltaic device of claim 2, wherein the material of p-type, n-type and i-type semiconductor layers are at least one of amorphous silicon based layers, and microcrystalline silicon based layer.

4. The photovoltaic device of claim 1, wherein the first microcrystalline silicon layer has a thickness between about 100 Å and about 500 Å.

5. The photovoltaic device of claim 1, wherein the first microcrystalline silicon layer is a p-type microcrystalline silicon based layer.

6. The photovoltaic device of claim 1, wherein the first microcrystalline silicon layer is a n-type microcrystalline silicon based layer.

7. The photovoltaic device of claim 1, wherein the transmitting conducting oxide layer is an oxide layer selected from a group consisting of tin oxide (SnO₂), indium tin oxide (ITO), zinc oxide (ZnO), or combinations thereof.

8. The photovoltaic device of claim 1, further comprising:
a second transparent conductive oxide layer disposed on the photoelectric conversion unit opposite the first transparent conductive oxide layer; and
a conductive layer disposed on the second transparent conductive oxide layer.

9. The photovoltaic device of claim 1, further comprising:
a second transparent conductive oxide layer disposed on the photoelectric conversion unit opposite the first transparent conductive oxide layer; and
a second photoelectric conversion unit disposed on the second transparent conductive oxide layer.

10. The photovoltaic device of claim 1, further comprising:
a second transparent conductive oxide layer disposed on the photoelectric conversion unit opposite the first transparent conductive oxide layer; and
a second microcrystalline silicon layer disposed between and in contact with the second transparent conductive oxide layer and the photoelectric conversion unit.

11. The photovoltaic device of claim 10, wherein the second microcrystalline silicon has a thickness between about 100 Å and about 500 Å.

12. The photovoltaic device of claim 9, further comprising:
a second microcrystalline silicon layer disposed on the second photoelectric conversion unit.

13. The photovoltaic device of claim 12, further comprising:
a third transparent conductive oxide layer disposed on the second microcrystalline silicon layer; and
a conductive layer disposed on the transparent conductive oxide layer.

14. A photovoltaic device, comprising:
a first microcrystalline silicon layer disposed between and in contact with a first photoelectric conversion unit and a first transparent conductive oxide layer;
a second microcrystalline silicon layer disposed on the top of the first photoelectric conversion unit; and
a second transparent conductive oxide layer disposed on the second microcrystalline silicon layer.

15. The photovoltaic device of claim 14, further comprising:
a second photoelectric conversion unit disposed between the first photoelectric conversion unit and the second microcrystalline silicon layer.

16. The photovoltaic device of claim 15, further comprising:
an intermediate transparent conductive oxide layer disposed between the first and the second photoelectric conversion unit.

17. The photovoltaic device of claim 15, wherein each of the first and the second photoelectric conversion units further comprises:
a p-type semiconductor layer;
a n-type semiconductor layer; and
an i-type semiconductor disposed between the p-type and n-type semiconductor layer.

18. The photovoltaic device of claim 17, wherein the p-type, n-type and i-type semiconductor layers are at least one of amorphous and microcrystalline silicon based layers.

19. The photovoltaic device of claim 14, wherein the first and the second microcrystalline silicon layers are at least one of p-type and n-type microcrystalline silicon based layer.

20. A method of forming a photovoltaic solar cell, comprising:
providing a substrate having a first transparent conductive oxide layer disposed thereon;
depositing a first microcrystalline silicon layer on the transparent conductive oxide layer; and
forming a first photoelectric conversion unit on the microcrystalline silicon layer.

21. The method of claim 20, wherein the step of forming the first photoelectric conversion unit further comprising:
depositing a p-type semiconductor layer on the transparent conductive oxide layer;
depositing a i-type semiconductor layer on the p-type semiconductor layer; and
depositing a n-type semiconductor layer on the i-type semiconductor layer.

22. The method of claim 21, wherein the p-type, n-type, and i-type semiconductor layers are at least one of amorphous silicon layer and microcrystalline silicon layer.

23. The method of claim 20, further comprising:
depositing a second microcrystalline silicon layer on the first photoelectric conversion unit.

24. The method of claim 23, further comprising:
depositing a second transparent conductive oxide layer on the second microcrystalline silicon layer.

25. The method of claim 24, further comprising:
depositing a conductive layer on the second transparent conductive oxide layer.

26. The method of claim 21, wherein the first and the second microcrystalline silicon layers are at least one of p-type microcrystalline silicon layer and n-type microcrystalline silicon layer.

27. The method of claim 23, further comprising:
forming a second photoelectric conversion unit between the first photoelectric conversion unit and the second microcrystalline silicon layer.

28. The method of claim 27, further comprising:
depositing an intermediate microcrystalline silicon layer between the first and the second photoelectric conversion unit.

29. A method for forming a photovoltaic solar cell, comprising:
providing a substrate having a first transparent conductive oxide layer disposed thereon;
depositing a p-type microcrystalline silicon layer on the transparent conductive oxide layer in a first processing chamber;
depositing a p-type amorphous silicon layer on the p-type microcrystalline silicon layer in the first processing chamber;
depositing an i-type amorphous silicon layer on the p-type amorphous silicon layer;
depositing a n-type amorphous silicon layer on the i-type amorphous silicon layer in a second processing chamber; and
depositing a n-type microcrystalline silicon layer on the n-type amorphous silicon layer in the second processing chamber.

30. The method of claim 29, further comprising:
depositing a second transparent conductive oxide layer on the n-type microcrystalline silicon layer; and
depositing a conductive layer on the second transparent conductive layer.
